(19) United States
(12) Patent Application Publication
(10) Pub. No.: US 2009/0061630 A1
(43) Pub. Date: Mar. 5, 2009

(54) Method for Chemical Mechanical Planarization of A Metal-containing Substrate

(75) Inventors: Bentley J. Palmer, Phoenix, AZ (US); Ann Marie Meyers, Chandler, AZ (US); Suresh Shrauti, Dallas, TX (US); Guangying Zhang, Phoenix, AZ (US); Ajoy Zutshi, Chandler, AZ (US)

Correspondence Address: AIR PRODUCTS AND CHEMICALS, INC.;PATENT DEPARTMENT, 7201 HAMILTON BOULEVARD, ALLENTOWN, PA, 181951501, US

(73) Assignee: DuPont Air Products Nanomaterials LLC, Allentown, PA (US)

(21) Appl. No.: 12/195,840

(22) Filed: Aug. 21, 2008

Related U.S. Application Data
(60) Provisional application No. 60/968,920, filed on Aug. 30, 2007.

(51) Int. Cl. H01L 21/304

(52) U.S. Cl. 438/693; 257/E21.239

(57) ABSTRACT

A method using an associated composition for chemical mechanical planarization of a metal-containing substrate (e.g., a copper substrate) is described. This method affords low dishing and local erosion levels on the metal during CMP processing of the metal-containing substrate.

### CROSS-REFERENCE TO RELATED APPLICATIONS

This patent application claims the benefit of U.S. Provisional Patent Application Ser. No. 60/968,920 filed 30 Aug. 2007.

### BACKGROUND OF THE INVENTION

This invention relates generally to the chemical-mechanical planarization (CMP) of metal substrates (e.g., copper substrates) on semiconductor wafers and slurry compositions therefor. In particular, the present invention relates to a CMP slurry composition that is effective for use in copper CMP and which affords low dishing levels on polished substrates following CMP processing. This invention is especially useful for copper CMP where low dishing on planarized substrates is desired.

Chemical mechanical planarization (chemical mechanical polishing, CMP) for planarization of semiconductor substrates is now widely known to those skilled in the art and has been described in numerous patents and open literature publications. An introductory reference on CMP is as follows: “Chemical-Mechanical Polish” by G. B. Shinn et al., Chapter 15, pages 415-460, in Handbook of Semiconductor Manufacturing Technology, editors: Y. Nishi and R. Doering, Marcel Dekker, New York City (2000).

In a typical CMP process, a substrate (e.g., a wafer) is placed in contact with a rotating polishing pad attached to a platen. A CMP slurry, typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

Silicon based semiconductor devices, such as integrated circuits (ICs), typically include a dielectric layer, which can be a low-k dielectric material, silicon dioxide, or other material. Multilevel circuit traces, typically formed from aluminum or an aluminum alloy or copper, are patterned onto the low-k or silicon dioxide substrate.

CMP processing is often employed to remove and planarize excess metal at different stages of semiconductor manufacturing. For example, one way to fabricate a multilevel copper interconnect or planar copper circuit traces on a silicon dioxide substrate is referred to as the damascene process. In a semiconductor manufacturing process typically used to form a multilevel copper interconnect, metallized copper lines or copper vias are formed by electrochemical metal deposition followed by copper CMP processing. In a typical process, the interlevel dielectric (ILD) surface is patterned by a conventional dry etch process to form vias and trenches for vertical and horizontal interconnects and make connection to the sublayer interconnect structures. The patterned ILD surface is coated with an adhesion-promoting layer such as titanium or tantalum and/or a diffusion barrier layer such as titanium nitride or tantalum nitride over the ILD surface and into the etched trenches and vias. The adhesion-promoting layer and/or the diffusion barrier layer is then overcoated with copper, for example, by a seed copper layer and followed by an electrochemically deposited copper layer. Electro-deposition is continued until the structures are filled with the deposited metal. Finally, CMP processing is used to remove the copper overlayer, adhesion-promoting layer, and/or diffusion barrier layer, until a planarized surface with exposed elevated portions of the dielectric (silicon dioxide and/or low-k) surface is obtained. The vias and trenches remain filled with electrically conductive copper forming the circuit interconnects.

When one-step copper CMP processing is desired, it is usually important that the removal rate of the metal and barrier layer material be significantly higher than the removal rate for dielectric material in order to avoid or minimize dishing of metal features or erosion of the dielectric. Alternatively, a multi-step copper CMP process may be employed involving the initial removal and planarization of the copper overburden, referred to as a step 1 copper CMP process, followed by a barrier layer CMP process. The barrier layer CMP process is frequently referred to as a barrier or step 2 copper CMP process. Previously, it was believed that the removal rate of the copper and the adhesion-promoting layer and/or the diffusion barrier layer must both greatly exceed the removal rate of dielectric so that polishing effectively stops when elevated portions of the dielectric are exposed. The ratio of the removal rate of copper to the removal rate of dielectric base is called the “selectivity” for removal of copper in relation to dielectric during CMP processing of substrates comprised of copper, tantalum and dielectric material. The ratio of the removal rate of tantalum to the removal rate of dielectric base is called the “selectivity” for removal of tantalum in relation to dielectric during CMP processing. When CMP slurries with high selectivity for removal of copper and tantalum in relation to dielectric are used, the copper layers are easily over-polished creating a depression or “dishing” effect in the copper vias and trenches. This feature distortion is unacceptable due to lithographic and other constraints in semiconductor manufacturing.

Another feature distortion that is unsuitable for semiconductor manufacturing is called “erosion.” Erosion is the topography difference between a field of dielectric and a dense array of copper vias or trenches. In CMP, the materials in the dense array maybe removed or eroded at a faster rate than the surrounding field of dielectric. This causes a topography difference between the field of dielectric and the dense copper array.

A typically used CMP slurry has two actions, a chemical component and a mechanical component. An important consideration in slurry selection is “passive etch rate.” The passive etch rate is the rate at which copper is dissolved by the chemical component alone and should be significantly lower than the removal rate when both the chemical component and the mechanical component are involved. A large passive etch rate leads to dishing of the copper trenches and copper vias, and thus, preferably, the passive etch rate is less than 10 nanometers per minute.

In relation to copper CMP, the current state of this technology involves use of a two-step process to achieve local and global planarization in the production of integrated circuit (“IC”) chips. During step 1 of a copper CMP process, the overburden copper is removed. Then step 2 of the copper CMP process follows to remove the barrier layer and achieve both local and global planarization. Generally, after removal of overburden copper in step 1, polished wafer surfaces have non-uniform local and global planarity due to differences in the step heights at various locations of the wafer surfaces. Low density features tend to have higher copper step heights whereas high density features tend to have low step heights. Due to differences in the step heights after step 1, step 2 copper CMP selective slurries with respect to tantalum to copper removal rates and copper to oxide removal rates are highly desirable. The ratio of the removal rate of tantalum to the removal rate of copper is called the “selectivity” for removal of tantalum in relation to copper during CMP processing of substrates comprised of copper, tantalum and dielectric material.

There are a number of theories as to the mechanism for chemical-mechanical polishing of copper. An article by D. Zeidler, Z. Stavreva, M. Ploetner, K. Drescher, “Characterization of Cu Chemical Mechanical Polishing by Electrochemical Investigations” (Microelectronic Engineering, 33(104), 259-265 (English) 1997), proposes that the chemical component forms a passivation layer on the copper changing the copper to a copper oxide. The copper oxide has different mechanical properties, such as density and hardness, than metallic copper and passivation changes the polishing rate of the abrasive portion. The above article by Gutmann, et al., entitled “Chemical-Mechanical Polishing of Copper with Oxide and Polymer Interlevel Dielectrics” (Thin Solid Films, 1995), discloses that the mechanical component abrades elevated portions of copper and the chemical component then dissolves the abraded material. The chemical component also passivates recessed copper areas minimizing dissolution of those portions.

These are two general types of layers that can be polished. The first layer is interlayer dielectrics (ILD), such as silicon oxide and silicon nitride. The second layer is metal layers such as tungsten, copper, aluminum, etc., which are used to connect the active devices.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal and enhancing the diffusion of reactants and products to and away from the surface by mixing and by reducing the thickness of the boundary layer.

While prior art CMP systems are capable of removing a copper overlayer from a silicon dioxide substrate, the systems do not satisfy the rigorous demands of the semiconductor industry. These requirements can be summarized as follows. First, there is a need for high removal rates of copper to satisfy throughput demands. Secondly, there must be excellent topography uniformity across the substrate. Finally, the CMP method must minimize dishing and local erosion effects on polished substrates as well as minimizing defectivity levels to satisfy ever increasing lithographic demands.

There is a significant need for copper CMP process(es) and slurry(s) that afford low dishing and local erosion effects especially in view of the fact that the semiconductor industry continues to move towards smaller and smaller feature sizes. The present invention provides a solution to this significant need.

### BRIEF SUMMARY OF THE INVENTION

In an embodiment, the invention is a method for chemical mechanical planarization of a surface having at least one feature thereon comprising a metal, said method comprising the steps of:
A) placing a substrate having the surface having the at least one feature thereon comprising the metal in contact with a polishing pad;
B) delivering a polishing composition to the surface comprising:
   a) an abrasive;
   b) a compound that is a free radical trap in an amount from about 0.1 ppm to about 4 ppm, preferably between about 0.1 ppm and about 1.8 ppm; and
   c) an oxidizing agent;
and
C) polishing the substrate with the polishing composition.

In another embodiment, the invention is a method for chemical mechanical planarization of a surface having at least one feature thereon comprising a metal, said method comprising the steps of:
A) placing a substrate having the surface having the at least one feature thereon comprising the metal in contact with a polishing pad;
B) delivering a polishing composition to the surface comprising:
   a) an abrasive;
   b) a compound that is a free radical trap in an amount below about 10 ppm selected from cinnamic acid or derivative thereof, said derivative comprising cinnamic acid having one or more of an oxygen-containing- or a nitrogen-containing-moiety, said moiety containing six or less carbon atoms; and
   c) an oxidizing agent;
   and
C) polishing the substrate with the polishing composition. As one example, the metal can be copper.

These polishing compositions are especially useful in slurries used to polish copper surfaces, for example step 1 and even for step 2 slurries. Step 1 slurries are generally characterized by a copper removal rate at 2 pounds per square inch (psi) down pressure of 2000 angstroms per minute, preferably 2500 angstroms per minute, in some cases 3000 angstroms per minute. Step 2 slurries are generally characterized by copper removal rates less than 1500 angstroms per minute and a copper to barrier material (e.g., tantalum) selectivity between about 0.5 to about 2. It is important to keep the levels of free radical trapping compounds below 4 parts per million (ppm), for example below about 2 ppm, that is, at 1.8 ppm or less. A preferred amount of the compound that is a free radical trap is between 0.5 ppm and 1.5 ppm. Amounts less than 1 ppm, for example 0.1 ppm to 0.8 ppm, are often useful. These very low levels of free radical trapping compounds reduce dishing while having a small to negligible effect on polishing rate and not leaving contamination on the polished wafer. For compositions where the levels of free radical trapping compounds are as high as 10 ppm, compared to the 1 ppm preferred in this invention, the polishing rate is measurably reduced in the composition having 10 ppm of the free radical trapping compound and dishing is actually worse in the composition having 10 ppm of the free radical trapping compound.

### DETAILED DESCRIPTION OF THE INVENTION

This invention is a method using associated polishing compositions (slurries) for polishing metal-containing substrates (e.g., a copper-containing substrate) and, in particular, is a method using a composition comprising an abrasive and a low level (ppm level) of a free radical trap. Such compositions have been surprisingly and unexpectedly found to afford low levels of dishing during the course of metal CMP (e.g., copper CMP) relative to comparable compositions without the free radical trap. The prevention of dishing/erosion of features on semiconductor substrates during CMP processing is becoming increasingly more important as the semiconductor industry trends to smaller and smaller feature sizes in the manufacture of integrated circuits.

Suitable free radical traps for the slurries and associated methods of this invention include, but are not limited to, ascorbic acid, benzoquinone, N,N-dimethyl-4-nitroaniline, 4-methoxyphenol, gallic acid, (−)-catechin gallate, (−)-epicatechin gallate, ellagic acid, 4-hydroxy-3-methoxycinnamic acid, 3,4-dihydroxycinnamic acid, rutin hydrate, diosimin, hesperidin, N-acetyl-L-cysteine, alpha-tocopherol, caffeic acid, and quercetin dihydrate. In another embodiment, the slurries may be free of any one or more of ascorbic acid, benzoquinone, N,N-dimethyl-4-nitroaniline, 4-methoxyphenol, gallic acid, (−)-catechin gallate, (−)-epicatechin gallate, ellagic acid, 4-hydroxy-3-methoxycinnamic acid, 3,4-dihydroxycinnamic acid, rutin hydrate, diosimin, hesperidin, N-acetyl-L-cysteine, alpha-tocopherol, caffeic acid, and quercetin dihydrate.

In an embodiment, the free radical trap has the formula (X₁)(X₂)(X₃)(X₄)(X₅)Ph-CH═CH—COOH, where X₁, X₂, X₃, X₄, and X₅ are independently hydrogen, hydroxyl, or C₁-C₆ alkoxy and Ph is a phenyl group. Alternatively the free radical trap comprises, consists essentially of, or consists of one or more compounds selected from a cinnamic acid derivative, said derivative or derivatives made by adding an oxygen-containing moiety or a nitrogen-containing moiety to cinnamic acid. Alternatively the free radical trap comprises, consists essentially of, or consists of cinnamic acid.

In an embodiment, the free radical trap is or comprises 4-hydroxy-3-methoxycinnamic acid. In another embodiment, the free radical trap is or comprises 3,4-dihydroxycinnamic acid. In an alternative embodiment, the free radical trap is or comprises ascorbic acid. Alternatively, the composition may comprise a free radical trap compound, preferably a second non-chelating free radical trap compound, in an amount between 0.1 and 1.8 ppm and also further comprise ascorbic acid. Alternatively, the composition may be free of ascorbic acid. In another embodiment, the free radical trap is or comprises benzoquinone. In another embodiment, the free radical trap is or comprises N,N-dimethyl-4-nitroaniline. In another embodiment, the free radical trap is or comprises 4-methoxyphenol. In another embodiment, the free radical trap is selected from the group consisting of rutin hydrate, diosimin, hesperidin, and N-acetyl-L-cysteine. In another embodiment, the free radical trap is selected from the group consisting of gallic acid, (−)-catechin gallate, (−)-epicatechin gallate, and ellagic acid. Alternatively the free radical trap comprises, consists essentially of, or consists of one or more compounds selected from 4-hydroxy-3-methoxycinnamic acid, 3,4-dihydroxycinnamic acid, rutin hydrate, diosimin, or ellagic acid. In another embodiment, the free radical trap is alpha-tocopherol. In another embodiment, the free radical trap is or comprises caffeic acid. In another embodiment, the free radical trap is or comprises quercetin dihydrate.

Levels of free radical trap useful in this invention range from about 0.1 ppm to about 4 ppm, and preferably range from about 0.1 ppm to 1.8 ppm. In an embodiment, the compound that is a free radical trap is present in an amount of less than or equal to 1.5 ppm. In another embodiment, the compound that is a free radical trap is present in an amount of less than or equal to 1 ppm. In still another embodiment, the compound that is a free radical trap is present in an amount of less than or equal to 0.5 ppm.

The slurry compositions and associated methods of this invention can have pH values that range from about 4 to about 10. In an embodiment, the pH ranges from about 5 to about 9; in another embodiment, the pH ranges from about 6 to about 8. In yet another embodiment, the pH ranges from about 6.5 to about 7.5. In most applications of this invention, a pH value near 7 (neutral) is preferred.

Suitable abrasives for this invention include, but are not limited to, alumina, ceria, germania, silica, titania, zirconia, and mixtures thereof. In one embodiment, the abrasive is silica (colloidal silica or fumed silica). In an embodiment, the abrasive is colloidal silica. The abrasive level in the slurry can broadly range from ia concentration of about 10 ppm to about 25 weight % of the total weight of the slurry. In a preferred embodiment, the abrasive level is relatively low and ranges from about 10 ppm to about 2 weight percent. In an embodiment, the abrasive level is about 10 ppm to about 1 weight percent; in another embodiment, the abrasive level ranges from about 25 ppm to about 100 ppm. In an alternative embodiment a preferred amount of abrasive is between 25 ppm and 300 ppm.

In embodiments of this invention having an oxidizing agent, the oxidizing agent can be any suitable oxidizing agent. Suitable oxidizing agents include, for example, one or more per-compounds, which comprise at least one peroxy group (—O—O—). Suitable per-compounds include, for example, peroxides, persulfates (e.g., monopersulfates and dipersulfates), percarbonates, and acids thereof, and salts thereof, and mixtures thereof. Other suitable oxidizing agents include, for example, oxidized halides (e.g., chlorates, bromates, iodates, perchlorates, perbromates, periodates, and acids thereof, and mixtures thereof, and the like), perboric acid, perborates, percarbonates, peroxyacids (e.g., peracetic acid, perbenzoic acid, m-chloroperbenzoic acid, salts thereof, mixtures thereof, and the like), permanganates, chromates, cerium compounds, ferricyanides (e.g., potassium ferricyanide), mixtures thereof, and the like. Some specific oxidizers that are useful in this invention include, but are not limited to, hydrogen peroxide, periodic acid, potassium iodate, potassium permanganate, ammonium persulfate, ammonium molybdate, ferric nitrate, nitric acid, potassium nitrate, ammonia, and other amine compounds, and mixtures thereof. Preferred oxidizing agents include, for example, hydrogen peroxide and urea-hydrogen peroxide.

In this invention, (hydrogen peroxide) H₂O₂ is used as a preferred oxidizing agent. When used, the concentration of the H₂O₂ is from about 0.2 weight % to about 5 weight % of the total weight of the slurry in an embodiment. In another embodiment the concentration of the H₂O₂ is from about 0.5 weight % to about 2 weight % of the total weight of the slurry. In another embodiment, the concentration of the H₂O₂ is from about 0.5 weight % to about 1.5 weight % of the total weight of the slurry.

Other chemicals that may be added to the CMP slurry composition include, for example, surfactants, pH-adjusting agents, acids, corrosion inhibitors, fluorine-containing compounds, chelating agents, nitrogen-containing compounds, and salts.

Suitable surfactant compounds that may be added to the slurry composition include, for example, any of the numerous nonionic, anionic, cationic or amphoteric surfactants known to those skilled in the art. The surfactant compounds may be present in the slurry composition in a concentration of about 0 weight % to about 1 weight % and, when present, are preferably present in a concentration of about 0.001 weight % to about 0.1 weight % of the total weight of the slurry. The preferred types of surfactants are nonionic, anionic, or mixtures thereof and are most preferably present in a concentration of about 10 ppm to about 1000 ppm of the total weight of the slurry. A suitable nonionic surfactant is Surfynol® 104E, which is a 50:50 mixture by weight of 2,4,7,9-tetramethyl-5-decyn-4,7-diol and ethylene glycol (solvent), (Air Products and Chemicals, Allentown, Pa.). Suitable anionic surfactants include cetyl trimethylammonium bromide and ammonium lauryl sulfate.

The pH-adjusting agent is used to improve the stability of the polishing composition, to improve the safety in handling and use, or to meet the requirements of various regulations. Suitable pH-adjusting agents to lower the pH of the polishing composition of the present invention include, but are not limited to, hydrochloric acid, nitric acid, sulfuric acid, chloroacetic acid, tartaric acid, succinic acid, citric acid, malic acid, malonic acid, various fatty acids, various polycarboxylic acids and mixtures thereof. Suitable pH-adjusting agents to raise the pH of the polishing composition of the present invention include, but are not limited to, potassium hydroxide, sodium hydroxide, ammonia, tetramethylammonium hydroxide, ethylenediamine, piperazine, polyethyleneimine, modified polyethyleneimines, and mixtures thereof.

Suitable acid compounds that may be added to the slurry composition include, but are not limited to, formic acid, acetic acid, propanoic acid, butanoic acid, pentanoic acid, hexanoic acid, heptanoic acid, octanoic acid, nonanoic acid, lactic acid, hydrochloric acid, nitric acid, phosphoric acid, sulfuric acid, hydrofluoric acid, malic acid, tartaric acid, gluconic acid, citric acid, phthalic acid, pyrocatechoic acid, pyrogallol carboxylic acid, gallic acid, tannic acid, and mixtures thereof. These acid compounds may be present in the slurry composition in a concentration of about 0 weight % to about 1 weight % of the total weight of the slurry.

To increase the removal rates of the slurry for tantalum and tantalum compounds as well as copper relative to silicon dioxide, fluorine-containing compounds may be added to the slurry composition. Suitable fluorine-containing compounds include, but are not limited to, hydrogen fluoride, perfluoric acid, alkali metal fluoride salt, alkaline earth metal fluoride salt, ammonium fluoride, tetramethylammonium fluoride, ammonium bifluoride, ethylenediammonium difluoride, diethylenetriammonium trifluoride, and mixtures thereof. The fluorine-containing compounds If present in the slurry composition are in a concentration of about 0.01 weight % to about 5 weight %, and are preferably present in a concentration of about 0.10 weight % to about 2 weight % of the total weight of the slurry. The preferred fluorine-containing compound is ammonium fluoride, most preferably present in a concentration of about 0 weight % to about 1 weight % of the total weight of the slurry.

Suitable chelating agents that may be added to the slurry composition include, but are not limited to, ethylenediaminetetracetic acid (EDTA), N-hydroxyethylethylenediaminetriacetic acid (NHEDTA), nitrilotriacetic acid (NTA), diethylenetriaminepentacetic acid (DPTA), ethanoldiglycinate, tricine, 2,2′-bipyridyl, tartaric acid, glutamic acid, aspartic acid, glutamine, L-aspartic acid, L-tryptophan, L-asparagine, L-arginine and mixtures thereof. The chelating agents may be present in the slurry composition in a concentration of about 0 weight % to about 3 weight %, and are preferably present in a concentration of about 0.05 weight % to about 0.20 weight % of the total weight of the slurry. Preferred chelating agents are tricine and EDTA and are most preferably present in a concentration of about 0.05 weight % to about 0.20 weight % of the total weight of the slurry. These chelating agents, while in many cases having ability to react with or neutralize free radicals, are not for purposes of this application considered to be free radical traps.

Suitable nitrogen-containing compounds that may be added to the slurry composition include, but are not limited to, ammonium hydroxide, hydroxylamine, monoethanolamine, diethanolamine, triethanolamine, diethyleneglycolamine, N-hydroxylethylpiperazine, polyethyleneimine, modified polyethyleneimines, and mixtures thereof. Suitable nitrogen-containing compounds also include various amino acids. Suitable amino acids include, but are not limited to, alanine, arginine, asparagine, aspartic acid, cysteine, glutamic acid, glutamine, glycine, histidine, isoleucine, leucine, lysine, methionine, phenylalanine, proline, serine, threonine, tryptophan, tyrosine, and valine. In an embodiment, the amino acid is glycine. The nitrogen-containing compounds may be present in the slurry composition in a concentration of about 0 weight % to about 1 weight %, and are preferably present in a concentration of about 0.01 weight % to about 0.20 weight % or about 0.2 weight % to about 0.80 weight % of the total weight of the slurry.

Suitable corrosion inhibitors for use in the slurry compositions and associated methods of this invention include benzotriazole, 6-tolyltriazole, 1,2,3-triazole, 1,2,4-triazole, 1-dodecanethiol, 3-amino-triazole, 3-amino-1,2,3-triazole-5-thiol, 1-phenyl-1H-tetrazole-5-thiol, 2-mercaptobenzothiazole, hexanethiol, 5-methyl-1H-benzotriazole, 2-amino-4-thiazole-acetic acid, dodecanethiol and combinations thereof.

Suitable salts that may be added to the slurry composition include, but are not limited to, ammonium persulfate, potassium persulfate, potassium sulfite, potassium carbonate, ammonium nitrate, potassium hydrogen phthalate, hydroxylamine sulfate, and mixtures thereof. The salts may be present in the slurry composition in a concentration of about 0 weight % to about 10 weight %, and are preferably present in a concentration of about 0 weight % to about 5 weight % of the total weight of the slurry. A preferred salt is ammonium nitrate and is most preferably present in a concentration of about 0 weight % to about 0.15 weight % of the total weight of the slurry.

Still other chemicals that can be added to the slurry compositions are biological agents such as bactericides, biocides and fungicides especially if the pH is around about 6 to 9. Suitable biocides, include, but are not limited to, 1,2-benzisothiazolin-3-one; 2(hydroxymethyl)amino ethanol; 1,3-dihydroxymethyl-5,5-dimethylhydantoin; 1-hydroxymethyl-5,5-dimethylhydantion; 3-iodo-2-propynyl butylcarbamate; glutaraldehyde; 1,2-dibromo-2,4-dicyanobutane; 5-chloro-2-methyl-4-isothiazoline-3-one; 2-methyl-4-isothiazolin-3-one; and mixtures thereof.

### Associated Method

The method of this invention entails use of the aforementioned composition (as disclosed supra) for chemical mechanical planarization of substrates comprised of metals and dielectric materials. In the methods, a substrate (e.g., a wafer) is placed face-down on a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to effect the removal of material to planarize the substrate.

The method of this invention using the associated polishing composition (slurry) is effective for CMP of a wide variety of substrates, including substrates having dielectric portions that comprise materials having dielectric constants less than 3.3 (low-k materials). Suitable low-k films in substrates include, but are not limited to, organic polymers, carbon-doped oxides, fluorinated silicon glass (FSG), inorganic porous oxide-like materials, and hybrid organic-inorganic materials. Representative low-k materials and deposition methods for these materials are summarized below.

| | | Deposition | |
|---|---|---|---|
| Vendor | Trade Name | Method | Material |
| Air Products and | MesoElk ® | Spin-on | Hybrid |
| Chemicals | | | organic-inorganic |
| Applied Materials | Black Diamond | CVD | Carbon-doped oxide |
| Dow Chemical | SiLK ™, | Spin-on | Organic polymer |
| | Porous SiLK ™ | | |
| Honeywell | NANOGLASS ® E | Spin-on | Inorganic oxide-like |
| Electronic | | | |
| Materials | | | |
| Novellus Systems | CORAL ® | PECVD | Carbon-doped oxide |

PECVD = Plasma enhanced chemical vapor deposition
CVD = chemical vapor deposition

Current copper CMP technology uses a two-step process to achieve local and global planarization in the production of IC chips. During copper CMP in step 1, the overburden copper is removed during IC fabrication processing. After removing the overburden copper in step 1, the polished surface still has not achieved local and global planarity due to differences in the step heights between high density and low density features on pattern wafers. After removing the overburden copper in step 1, a high tantalum to copper selectivity is desired to achieve local and global planarization. A challenging task is to maintain high tantalum removal while achieving high tantalum to copper selectivity and protection of the low lying copper regions. If the low lying copper regions are not protected during polishing, this results in a defect commonly known as “dishing”. A slurry which can increase the tantalum to copper selectivity during polishing in step 2 can reduce “dishing” by providing wide overpolish window during chip fabrication processing.

In an embodiment, the invention is a method for chemical mechanical planarization of a surface having at least one feature thereon comprising a metal, wherein the metal is copper.

The present invention is further demonstrated by the examples below.

### GLOSSARY

COMPONENTS

| | |
|---|---|
| Colloidal silica | |
| PETEOS | Plasma enhanced deposition of tetraethoxy |
| | silane, dielectric oxide layer. |
| Polishing Pad | Polishing pad, Politex ®, and IC1000 were used |
| | during CMP, supplied by Rodel, Inc, Phoenix, AZ. |
| TEOS | Tetraethyl orthosilicate |

PARAMETERS

| | |
|---|---|
| General | |
| Å: | angstrom(s) - a unit of length |
| BP: | back pressure, in psi units |
| CMP: | chemical mechanical planarization = chemical |
| | mechanical polishing |
| CS: | carrier speed |
| DF: | Down force: pressure applied during CMP, units psi |
| min: | minute(s) |
| ml: | milliliter(s) |
| mV: | millivolt(s) |
| psi: | pounds per square inch |
| PS: | platen rotational speed of polishing tool, in rpm |
| | (revolution(s) per minute) |
| SF: | slurry flow, ml/min |

Removal Rates and Selectivities

| | |
|---|---|
| Cu RR 1 psi | Measured copper removal rate at 1 psi down pressure |
| | of the CMP tool on a copper-covered wafer |
| | (e.g., blanket wafer) |
| Ta RR 1 psi | Measured tantalum removal rate at 1 psi down |
| | pressure of the CMP tool on a tantalum-covered wafer |
| | (e.g., blanket wafer) |

TEOS RR 1 psi Measured TEOS removal rate at 1 psi down pressure of the CMP tool on a TEOS wafer (e.g., blanket wafer)
PETEOS RR 1 psi Measured PETEOS removal rate at 1 psi down pressure of the CMP tool on a PETEOS wafer (e.g., blanket wafer)

### EXAMPLES

### General

All percentages are weight percentages unless otherwise indicated.

### CMP Methodology

In the examples presented below, CMP experiments were run using the procedures and experimental conditions given below.

### CMP Tool

The CMP tool that was used is a Mirra® tool, manufactured by Applied Materials, Inc., 3050 Bowers Avenue, Santa Clara, Calif., 95054. A Rodel Politex® embossed pad, supplied by Rodel, Inc, 3804 East Watkins Street, Phoenix, Ariz., 85034, was used on the platen for the blanket wafer polishing studies. Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton® OX-K colloidal silica, supplied by DuPont Air Products NanoMaterials L.L.C., at baseline conditions.

In blanket wafers studies, groupings were made to simulate successive film removal: first copper, next tantalum, and finally the PETEOS. The tool mid-point conditions were: table speed; 123 rpm, head speed; 112 rpm, membrane pressure, 2.0 psi; inter-tube pressure, 1.0 psi; slurry flow, 200 ml/min

Defect counts were measured using a Surfscane SP1 instrument manufactured by KLA Tencore, located at 1-Technology Drive, Milipitas, Calif., 95035. This instrument is a laser-based wafer surface inspection system. Using this instrument, particles and surface defects on unpatterned substrates were obtained. The particle count was recorded as number of defects, location of defects, and the size of defects. Also, this instrument was used for measuring surface quality through characterization of surface roughness and classification of defects such as haze, pits, scratches, mounds, dimples, and stacking faults. Experiments were done by loading the wafers under vacuum wand into a cassette, followed by placing the cassette on the SP1 instrument using a Novellus® copper calibration standard. This method classifies defects ranging from 0.2 micron to 2.5 micron.

### Wafers

Polishing experiments were conducted using electrochemically deposited copper, tantalum, and PETEOS wafers. These blanket wafers were purchased from Silicon Valley Microelectronics, 1150 Campbell Ave, CA, 95126. The film thickness specifications are summarized below:

PETEOS: 15,000 Å on silicon
Copper: 10,000 Å electroplated copper/1,000 Å copper seed/250 Å Ta on silicon
Tantalum: 2000 Å/5,000 Å thermal oxide on silicon

### Example 1

Components of mixture for preparing 2500 kg formulated slurry:
1. 52 ppm Polyedge 2002 (Grace Davison, 7500 Grace Dr., Columbia, Md. 21044) (Colloidal Silica)
2. 262.5 ppm Triazole
3. 0.52% glycine
4. 0.000145005% Kathon CG (antimicrobial agent) (0.73 g of a 1.5% solution) (Chempoint, 411 108th Ave NE Step 1050, Bellevue, Wash. 21044)
5. 2401.03 g DIW
6.1% H2O2
7. Adjusted to pH=7 with 5% KOH

In a 5-liter beaker, 2401.03 grams of deionized water was added and allowed to stir using a magnetic stirrer for 2 minutes. Under agitation, 0.28 g of a 46.33% solution of colloidal silica was added. To this solution, was added 1.99 g of a 33% solution of 1,2,4-triazole; 13.13 g of glycine; 0.73 g of a 1.5% solution Kathon CG. 88.33 grams of a 30% solution of hydrogen peroxide were added directly before polishing.

### Example 2

Components of mixture for preparing 2.5 kg formulated slurry
1. DIW (2399.78 g)
2. 52 ppm of Colloidal silica (0.28 g of a 46.33% solution)
3. 262.5 ppm of Triazole (1.99 g of a 33% solution)
4. 0.52% glycine (13.13 g)
5. 1 ppm Benzoquinone (1.25 g of a 0.1% solution)
6. 1% H2O2 (83.33 g of a 30% solution)
7. 0.000145005% Kathon (0.73 g of a 1.5% solution)
8. Adjusted to pH=7 with 5% KOH
   Procedure for mixing the slurry, 2.5 kg batch size

In a 5-liter beaker, 2399.78 grams of deionized water was added and allowed to stir using a magnetic stirrer for 2 minutes. Under agitation, 0.28 g of a 46.33% solution of colloidal silica was added. To this solution, was added 1.99 g of a 33% solution of 1,2,4-triazole; 13.13 g of glycine; 1.25 g of a 0.1% solution of benzoquinone; 0.73 g of a 1.5% solution of Kathon GC and 88.33 grams of a 30% solution of hydrogen peroxide were added directly before polishing.

### Example 3

In a 5-liter beaker, 2399.78 grams of deionized water was added and allowed to stir using a magnetic stirrer for 2 minutes. Under agitation, 0.28 g of a 46.33% solution of colloidal silica was added. To this solution, was added 1.99 g of a 33% solution of 1,2,4-triazole; 13.13 g of glycine; 1.25 g of a 0.1% solution of trans-4-hydroxy-3-methoxycinnamic acid. 88.33 grams of a 30% solution of hydrogen peroxide were added directly before polishing.

Components of mixture for preparing 2.5 kg formulated slurry
1. DIW (2399.78 g)
2. 52 ppm of Colloidal silica (0.28 g of a 46.33% solution)
3. 262.5 ppm of Triazole (1.99 g of a 33% solution)
4. 0.52% Glycine (13.13 g)
5. 1 ppm Trans-4-Hydroxy-3-Methoxycinnamic Acid (1.25 g of a 0.1% solution)
6. 1% H2O2 (83.33 g of a 30% solution)
7. 0.000145005% Kathon GC (0.73 g of a 1.5% solution)
8. Adjusted to pH=7 with 5% KOH

The compositions of Examples 1-3 and the results obtained using these compositions for copper CMP are summarized in Table 1.

TABLE 1
Illustrating the improved dishing and removal rates achieved using a free
radical trap (Examples 2 & 3) versus an identical system with no free radical trap
(Example 1)

| | Example 1 | | |
|---|---|---|---|
| | (Comparative) | Example 2 | Example 3 |
| Formulation | 52 ppm Polyedge 2002 | 52 ppm Polyedge 2002 | 52 ppm Polyedge 2002 |
| | 262.5 ppm Triazole | 262.5 ppm Triazole | 262.5 ppm Triazole |
| | 0.52% glycine | 0.52% glycine | 0.52% glycine |
| | 0.000145005% Kathon | 0.000145005% Kathon | 0.000145005% Kathon |
| | CG | CG | CG |
| | (No free radical trap) | 1 ppm 1,4- | 1 ppm Trans-4- |
| | | Benzoquinone | hydroxy-3- |
| | | | methoxycinnamic Acid |
| | 1% H2O2 | 1% H2O2 | 1% H2O2 |
| | 2401.03 g DIW | 2399.78 g DIW | 2399.78 g DIW |
| Cu RR 1 psi | 2392 \acute{Å}/min | 2513 \acute{Å}/min | 2717 \acute{Å}/min |
| Dishing in \acute{Å} | 420, 536, 762 | 376, 316, 793 | 267, 287, 484 |
| on 100 um | | | |
| line (C, M, E) | | | |

C = dishing value at center of wafer;
M = dishing value at middle of wafer;
E = dishing value at edge of wafer;
DIW = deionized water.

The compositions of Examples 4-5 and the results obtained using these compositions for copper CMP are summarized in Table 2 below.

TABLE 2

| | Example 4 | Example 5 |
|---|---|---|
| Formulation | 52 ppm Polyedge 2002 | 52 ppm Polyedge 2002 |
| | 262.5 ppm Triazole | 262.5 ppm Triazole |
| | 0.52% glycine | 0.52% glycine |
| | 0.000145005% Kathon | 0.000145005% Kathon |
| | CG | CG |
| | 10 ppm L-Ascorbic | 1 ppm L-Ascorbic Acid |
| | Acid | |
| | 1% H2O2 | 1% H2O2 |
| | 2401.03 g DIW | 2399.78 g DIW |
| Cu RR 1 psi | 2753 \acute{Å}/min | 3032 \acute{Å}/min |
| Dishing in \acute{Å} | 411, 302, 818 | 222, 204, 849 |
| on 100 um | | |
| line (C, M, E) | | |

C = dishing value at center of wafer;
M = dishing value at middle of wafer;
E = dishing value at edge of wafer.

### Example 4

In a 5-liter beaker, 2399.78 grams of deionized water was added and allowed to stir using a magnetic stirrer for 2 minutes. Under agitation, 0.28 g of a 46.33% solution of colloidal silica was added. To this solution, was added 1.99 g of a 33% solution of 1,2,4-triazole; 13.13 g of glycine; 12.5 g of a 0.1% solution of L-Ascorbic Acid. 88.33 grams of a 30% solution of hydrogen peroxide were added directly before polishing.

Components of mixture for preparing 2.5 kg formulated slurry
9. DIW (2399.78 g)
10. 52 ppm of Colloidal silica (0.28 g of a 46.33% solution)
11. 262.5 ppm of Triazole (1.99 g of a 33% solution)
12. 0.52% Glycine (13.13 g)
13. 10 ppm L-Ascorbic Acid (12.5 g of a 0.1% solution)
14. 1% H2O2 (83.33 g of a 30% solution)
15. 0.000145005% Kathon CG (0.73 g of a 1.5% solution)
16. Adjusted to pH=7 with 5% KOH

### Example 5

In a 5-liter beaker, 2399.78 grams of deionized water was added and allowed to stir using a magnetic stirrer for 2 minutes. Under agitation, 0.28 g of a 46.33% solution of colloidal silica was added. To this solution, was added 1.99 g of a 33% solution of 1,2,4-triazole; 13.13 g of glycine; 1.25 g of a 0.1% solution of L-Ascorbic Acid. 88.33 grams of a 30% solution of hydrogen peroxide were added directly before polishing.

Components of mixture for preparing 2.5 kg formulated slurry
17. DIW (2399.78 g)
18. 52 ppm of Colloidal silica (0.28 g of a 46.33% solution)
19. 262.5 ppm of Triazole (1.99 g of a 33% solution)
20. 0.52% Glycine (13.13 g)
21. 1 ppm L-Ascorbic Acid (1.25 g of a 0.1% solution)
22. 1% H2O2 (83.33 g of a 30% solution)
23. 0.000145005% Kathon CG (0.73 g of a 1.5% solution)
24. Adjusted to pH=7 with 5% KOH

As the dishing data of Table 1 illustrates, both trans-4-hydroxy-3-methoxycinnamic acid (Example 3) and 1,4-benzoquinone (Example 2) were surprisingly effective with each one present at 1 ppm in the polishing compositions in reducing dishing during CMP using these compositions in comparison to a control composition (Example 1) that had no free radical trap present. Dishing was reduced from 420 angstroms (center value) in the control to 376 angstroms (center value) in the composition containing 1 ppm of benzoquinone and to 267 angstroms (center value) in the composition containing 1 ppm of trans-4-hydroxy-3-methoxycinnamic acid. Furthermore, surprisingly the copper removal rates were observed to increase substantially with these components being present in the slurries—from 2392 angstroms/minute for the control slurry to 2513 angstroms/minute in the slurry containing benzoquinone at 1 ppm and to 2717 angstroms/minute in the slurry containing trans-4-hydroxy-3-methoxycinnamic acid at 1 ppm.

As the dishing data of Table 2 illustrates, ascorbic acid was also surprisingly effective in reducing dishing and increasing the copper removal rate in comparison to the control (Example 1 in Table 1). Dishing was reduced from 420 angstroms (center value) in the control to 222 angstroms (center value) using the composition shown in Example 5 with ascorbic acid present at 1 ppm. It is possible to have too much of the free radical trap compound present. Comparing the levels of free radical trapping compounds as low as 10 ppm compared to the 1 ppm preferred in this invention, the polishing rate is measurably reduced in the composition having 10 ppm of the free radical trapping compound and dishing is actually worse in the composition having 10 ppm of the free radical trapping compound. The copper removal rate increased substantially from 2392 angstroms/minute to 3032 angstroms/minute. Example 5 shows the effect of ascorbic acid being present at 10 ppm. The effect of increasing the ascorbic acid level from 1 ppm to 10 ppm is adverse in increasing the level of dishing (from 222 angstroms (center) to 411 angstroms (center) and in reducing the copper removal rate (from 3032 angstroms/minute to 2753 angstroms/minute).

The invention is merely intended to be illustrated by, and not to be limited to, the examples described above.

1. A method for chemical mechanical planarization of a surface having at least one feature thereon comprising a metal, said method comprising the steps of:
A) placing a substrate having the surface having the at least one feature thereon comprising the metal in contact with a polishing pad;
B) delivering a polishing composition to the surface comprising:
a) an abrasive;
b) a compound that is a free radical trap in an amount from 0.1 ppm to 1.8 ppm; and
c) an oxidizing agent;
and
C) polishing the substrate with the polishing composition.

2. The method of claim 1 wherein the compound that is a free radical trap is present in an amount of less than or equal to 1.5 ppm.

3. The method of claim 2 wherein the compound that is a free radical trap is present in an amount of less than or equal to 1 ppm.

4. The method of claim 3 wherein the compound that is a free radical trap is present in an amount of less than or equal to 0.5 ppm.

5. The method of claim 1 wherein the metal is copper.

6. The method of claim 1 wherein the free radical trap has the formula (X₁)(X₂)(X₃)(X₄)(X₅)Ph-CH═CH—COOH, where X₁, X₂, X₃, X₄, and X₅ are independently selected from the group consisting of hydrogen, hydroxyl, or C₁-C₆ alkoxy and Ph is a phenyl group.

7. The method of claim 6 wherein the free radical trap is 4-hydroxy-3-methoxycinnamic acid.

8. The method of claim 6 wherein the free radical trap is 3,4-dihydroxycinnamic acid.

9. The method of claim 1 wherein the free radical trap is ascorbic acid.

10. The method of claim 1 wherein the free radical trap is benzoquinone.

11. The method of claim 1 wherein the free radical trap is N,N-dimethyl-4-nitroaniline.

12. The method of claim 1 wherein the free radical trap is 4-methoxyphenol.

13. The method of claim 1 wherein the free radical trap is selected from the group consisting of rutin hydrate, diosimin, hesperidin, and N-acetyl-L-cysteine.

14. The method of claim 1 wherein the free radical trap is selected from the group consisting of gallic acid, (−)-catechin gallate, (−)-epicatechin gallate, and ellagic acid.

15. The method of claim 1 wherein the free radical trap is alpha-tocopherol.

16. The method of claim 1 wherein the free radical trap is caffeic acid.

17. The method of claim 1 wherein the free radical trap is quercetin dehydrate.

18. The method of claim 1 wherein the polishing composition has a pH from 6 to 8.

19. The method of claim 1 wherein the oxidizing agent is hydrogen peroxide.

20. A method for chemical mechanical planarization of a surface having at least one feature thereon comprising a metal, said method comprising the steps of:
A) placing a substrate having the surface having the at least one feature thereon comprising the metal in contact with a polishing pad;
B) delivering a polishing composition to the surface comprising:
a) an abrasive;
b) a compound that is a free radical trap in an amount from 0.1 ppm to below 10 ppm selected from cinnamic acid or derivative thereof, said derivative comprising cinnamic acid having one or more of an oxygen-containing- or a nitrogen-containing-moiety, said moiety containing six or less carbon atoms; and
c) an oxidizing agent;
and
C) polishing the substrate with the polishing composition.
